(19) United States
(12) Patent Application Publication
(10) Pub. No.: US 2021/0043157 A1
(43) Pub. Date: Feb. 11, 2021

(54) TIMING CONTROL BOARD AND DISPLAY DEVICE

(71) Applicant: TCL CHINA STAR OPTOELECTRONICS TECHNOLOGY CO., LTD., Shenzhen, Guangdong (CN)

(72) Inventors: Xiaoli FANG, Shenzhen, Guangdong (CN); Guangxing XIAO, Shenzhen, Guangdong (CN); Keyuan LIU, Shenzhen, Guangdong (CN); Jianjun XIE, Shenzhen, Guangdong (CN)

(21) Appl. No.: 16/616,505

(22) PCT Filed: Nov. 13, 2019
(86) PCT No.: PCT/CN2019/117789

§ 371 Date: Nov. 25, 2019

(30) Foreign Application Priority Data
Aug. 9, 2019 (CN) 201910732308.8

(51) Int. Cl. G09G 5/00; H05K 1/02

(52) U.S. Cl. CPC G09G 5/003; G09G 2310/08; H05K 1/0203

(57) ABSTRACT

A timing control (TCON) board and a display device are provided. The TCON board includes a TCON chip and a CB. A plurality of heat dissipating terminals are provided to commonly connect the TCON chip to the CB, increasing a total contact area of the TCON board and the CB. Therefore, heat dissipation efficiency of the TCON chip is improved. At the same time, the heat dissipating terminals greatly reduce a pseudo connection percentage. Hence, heat dissipation performance and electrical performance of the entire TCON chip are avoided to be impacted.

### FIELD OF INVENTION

The present disclosure relates to a technical field of displays, and more particularly to a timing control (TCON) board and a display device.

### BACKGROUND OF INVENTION

Currently, for a timing control (TCON) chip, a chip in a form of plastic quad flat package (QFP), connected to a control board (CB), only one first heat dissipating terminal is disposed at a center of a bottom of the TCON chip, and is connected to a ground (GND).

However, when the first heat dissipating terminal is actually being connected, because of a deficiency in a connecting technology or connecting material, a problem that a connection is pseudo, or an effective connection point is not formed is generated. Therefore, heat dissipation performance of the TCON chip is poor. The first heat dissipating terminal may even be disconnected from the GND, affecting electrical performance of the chip.

Therefore, the existing Timing control (TCON) board has a problem of poor heat dissipation performance, which needs to be solved.

### SUMMARY OF INVENTION

Technical problems of the present disclosure are as follows.

The present disclosure provides a timing control (TCON) board, to alleviate a problem that an existing TCON board has poor heat dissipation performance.

Technical solutions of the present disclosure are as follows.

In order to solve the aforementioned problem, the present disclosure provides the following technical solutions.

The present disclosure provides a TCON board, including:

a TCON chip including a first signal terminal and at least two first heat dissipating terminals;

a control board (CB) including a second signal terminal disposed corresponding to the first signal terminal, and at least two second heat dissipating terminals disposed corresponding to the corresponding first heat dissipating terminals;

a first connecting member configured to connect the first signal terminal to the second signal terminal; and

at least two second connecting members configured to connect the first heat dissipating terminals to the corresponding second heat dissipating terminals.

In the TCON board provided by the present disclosure, the first heat dissipating terminals are located at a middle region of the TCON chip.

In the TCON board provided by the present disclosure, the middle region has side length half of side length of the TCON chip.

In the TCON board provided by the present disclosure, a corresponding distance between each adjacent two of the first heat dissipating terminals is 0.8 to 1 mm.

In the TCON board provided by the present disclosure, a corresponding distance between each two opposite sides of the first heat dissipating terminals is 1.8 to 2.0 mm.

In the TCON board provided by the present disclosure, all of the first heat dissipating terminals have a same size.

In the TCON board provided by the present disclosure, there are at least two of the first heat dissipating terminals having different corresponding sizes.

In the TCON board provided by the present disclosure, the first heat dissipating terminals are arranged in an array.

In the TCON board provided by the present disclosure, the first heat dissipating terminals are arranged in an axisymmetric manner.

In the TCON board provided by the present disclosure, the first heat dissipating terminals have one or more of an octagonal shape, a quadrilateral shape, and a circular shape.

At the same time, the present disclosure provides a display device, including: a TCON board, wherein the TCON board includes:

a TCON chip including a first signal terminal and at least two first heat dissipating terminals;

a CB including a second signal terminal disposed corresponding to the first signal terminal, and at least two second heat dissipating terminals disposed corresponding to the corresponding first heat dissipating terminals;

a first connecting member configured to connect the first signal terminal to the second signal terminal; and

at least two second connecting members configured to connect the first heat dissipating terminals to the corresponding second heat dissipating terminals.

In the display device of the present disclosure, the first heat dissipating terminals are located at a middle region of the TCON chip.

In the display device of the present disclosure, the middle region has side length half of side length of the TCON chip.

In the display device of the present disclosure, a corresponding distance between each adjacent two of the first heat dissipating terminals is 0.8 to 1 mm.

In the display device of the present disclosure, a corresponding distance between each two opposite sides of the first heat dissipating terminals is 1.8 to 2.0 mm.

In the display device of the present disclosure, all of the first heat dissipating terminals have a same size.

In the display device of the present disclosure, there are at least two of the first heat dissipating terminals having different corresponding sizes.

In the display device of the present disclosure, the first heat dissipating terminals are arranged in an array.

In the display device of the present disclosure, the first heat dissipating terminals are arranged in an axisymmetric manner.

In the display device of the present disclosure, the first heat dissipating terminals have one or more of an octagonal shape, a quadrilateral shape, and a circular shape.

Advantages are as follows.

The present disclosure provides the TCON board including the TCON chip and the CB. The TCON chip is provided with the first heat dissipating terminals. The CB is provided with the second heat dissipating terminals disposed corresponding to the corresponding first heat dissipating terminals. The first heat dissipating terminals are connected to the corresponding second heat dissipating terminals. The heat dissipating terminals are provided to commonly connect the TCON chip to the CB, increasing a total contact area of the TCON board and the CB. Therefore, heat dissipation efficiency of the TCON chip is improved. At the same time, the heat dissipating terminals greatly reduce a pseudo connection percentage. Even if a truly effective connection point is not formed for one of the heat dissipating terminals, at least one connection point for at least one other corresponding heat dissipating terminal of the heat dissipating terminals is not affected. Hence, heat dissipation performance and electrical performance of the entire TCON chip are avoided to be impacted. The problem that the existing TCON board has the poor heat dissipation performance is alleviated.

### DESCRIPTION OF DRAWINGS

In order to describe a technical solution in embodiments or related art more clearly, drawings required to be used by the embodiments or the related art are briefly introduced below. Obviously, the drawings in the description below are only some embodiments of the present disclosure. With respect to persons of ordinary skill in the art, under a premise that inventive efforts are not made, other drawings may be obtained based on these drawings.

FIG. 1 is a schematic diagram illustrating a structure of a timing control (TCON) board in accordance with some embodiments of the present disclosure.

FIG. 2(a) is a schematic diagram illustrating a TCON chip of a first type of the TCON board in accordance with some embodiments of the present disclosure.

FIG. 2(b) is a schematic diagram illustrating a control board (CB) of the first type of the TCON board in accordance with some embodiments of the present disclosure.

FIG. 3(a) is a schematic diagram illustrating a TCON chip of a second type of the TCON board in accordance with some embodiments of the present disclosure.

FIG. 3(b) is a schematic diagram illustrating a CB of the second type of the TCON board in accordance with some embodiments of the present disclosure.

FIG. 4(a) is a schematic diagram illustrating a TCON chip of a third type of the TCON board in accordance with some embodiments of the present disclosure.

FIG. 4(b) is a schematic diagram illustrating a CB of the third type of the TCON board in accordance with some embodiments of the present disclosure.

FIG. 5(a) is a schematic diagram illustrating a TCON chip of a fourth type of the TCON board in accordance with some embodiments of the present disclosure.

FIG. 5(b) is a schematic diagram illustrating a CB of the fourth type of the TCON board in accordance with some embodiments of the present disclosure.

### DETAILED DESCRIPTION OF PREFERRED EMBODIMENTS

The description of each embodiment below refers to respective accompanying drawing(s), to illustrate exemplarily specific embodiments of the present disclosure that may be practiced. Directional terms mentioned in the present disclosure, such as “upper”, “lower”, “front”, “back”, “left”, “right”, “inner”, “outer”, “side”, etc., are only directions by referring to the accompanying drawings, and thus the used directional terms are used to describe and understand the present disclosure, but the present disclosure is not limited thereto. In the drawings, structurally similar units are labeled by the same reference numerals.

A timing control (TCON) board provided by the present disclosure may alleviate a problem that an existing TCON board has poor heat dissipation performance.

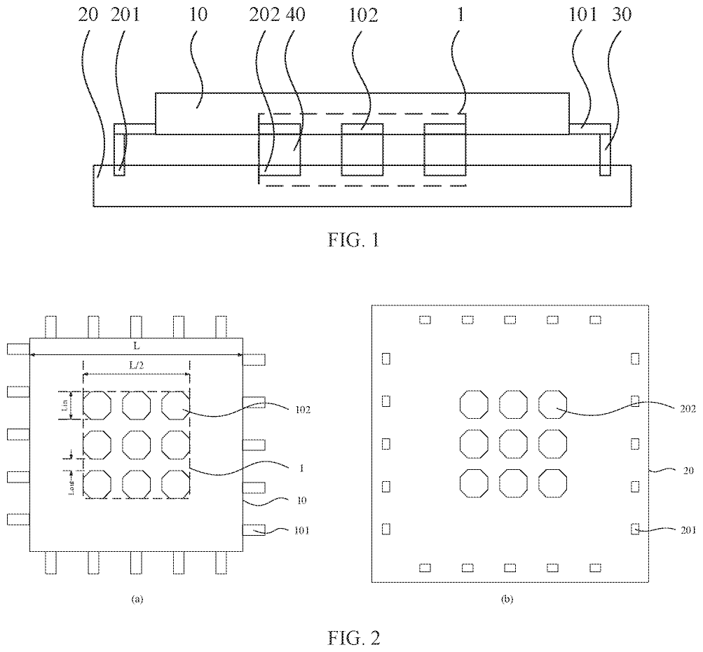

As illustrated in FIG. 1, the TCON board provided by some embodiments of the present disclosure includes:

a TCON chip 10 including a first signal terminal 101 and at least two first heat dissipating terminals 102;

a control board (CB) 20 including a second signal terminal 201 disposed corresponding to the first signal terminal 101, and at least two second heat dissipating terminals 202 disposed corresponding to the corresponding first heat dissipating terminals 102;

a first connecting member 30 configured to connect the first signal terminal 101 to the second signal terminal 201; and

at least two second connecting members 40 configured to connect the first heat dissipating terminals 102 to the corresponding second heat dissipating terminals 202.

For the TCON board provided by some embodiments of the present disclosure, the heat dissipating terminals are provided to commonly connect the TCON chip to the CB, increasing a total contact area of the TCON board and the CB. Therefore, heat dissipation efficiency of the TCON chip is improved. At the same time, the heat dissipating terminals greatly reduce a pseudo connection percentage. Even if a truly effective connection point is not formed for one of the heat dissipating terminals, at least one connection point for at least one other corresponding heat dissipating terminal of the heat dissipating terminals is not affected. Hence, heat dissipation performance and electrical performance of the entire TCON chip are avoided to be impacted. The problem that the existing TCON board has the poor heat dissipation performance is alleviated.

The following is a further illustrative description for the TCON board provided by the present. An example of the TCON board having a size of 14 mm*14 mm in conjunction with specific embodiments is used.

In some embodiments, as illustrated in FIGS. 1 to 5, the first heat dissipating terminals 102 are located at a middle region 1 of the TCON chip. A size of the middle region 1 is determined by a size of the TCON chip. The size of the middle region 1 is about half of the size of the TCON chip. When an occupied area of the middle region 1 is too small, an occupied area of the first heat dissipating terminals 102 is correspondingly small, causing a contact area of the TCON chip 10 and a ground (GND) to be small. Therefore, it is disadvantageous for the TCON chip 10 to dissipate heat through the large-area copper-clad GND, disadvantageous for enhancing heat dissipation performance of the TCON chip 10, and at the same time, disadvantageous for eliminating static electricity, and preventing external interference. When an occupied area of the middle region 1 is too large, the middle region 1 may be too close to a boarder of the TCON chip 10, thereby causing one or more of the first heat dissipating terminals 102 at an edge to be bridged with the first signal terminal 101.

Inside the middle region 1, different arrangement manners of the first heat dissipating terminals 102 cause different corresponding connection effects of the CB 20 and the TCON chip 10, thereby differently affecting corresponding electrical performance and corresponding heat dissipation performance of the TCON chip 10. In the following embodiments, the first heat dissipating terminals 102 connected to the corresponding second heat dissipating terminals 202 have a same size.

The size and a number of the first heat dissipating terminals 102 are determined by the size of the middle region 1. Based on the size of the middle region 1, and corresponding requirements of power amount and electrical performance of the TCON chip 10, a distribution of the first heat dissipating terminals 102, the size of the first heat dissipating terminals 102, and the number of first heat dissipating terminals 102 are arranged, to cause a coverage percentage of the second connecting members 40 to be as large as possible. Hence, a contact area of the first heat dissipating terminals 102 and the GND is increased. Heat dissipation performance and electrical performance of the TCON chip 10 are increased.

In some embodiments, each second connecting member 40 is corresponding solder. Material of each solder is one of tin-lead alloy solder, antimony-contained solder, cadmium-contained solder, silver-contained solder, and copper-contained solder. Each solder includes a solder wire, a solder bar, a solder paste, or a solder ball. In the present embodiments, it is noted that each adjacent set of the first heat dissipating terminals 102 forming a corresponding acute angle or using corresponding large-area copper foil need to be avoided as much as possible. Each adjacent set of the first heat dissipating terminals 102 forming the acute angle causes difficulty in wave soldering, and risk of bridging. Each adjacent set of the first heat dissipating terminals 102 using the large-area copper foil dissipates heat too fast, thereby causing soldering to be uneasy.

In the present embodiments, the larger the total area occupied by the first heat dissipating terminals 102 is, the greater the contact of the TCON chip 10 with the GND is. Therefore, an effect of dissipating heat through the large-area copper-clad GND is better. In another aspect, in the same middle region 1, the more the number of the first heat dissipating terminals 102 arranged is, the smaller the size of each of the first heat dissipating terminals 102 is. In a high-temperature soldering process, a corresponding escape path of gas produced by cracking a corresponding flux in each solder is shorter. At the same time, corresponding gaps between adjacent sets of the first heat dissipating terminals 102 that serve as corresponding gas escape channels are more, thereby facilitating the gas to escape in time. Therefore, corresponding areas and a number of voids are effectively reduced. Corresponding stress of each land and corresponding surface tension of the corresponding solder are increased. A pseudo soldering percentage is greatly reduced. Risk of solder paste slump which causes pseudo soldering is reduced. Overall mechanical performance of the first heat dissipating terminals 102 is effectively increased. An effective contact area of the TCON chip 10 and the GND is increased. The heat dissipation performance of the TCON chip 10 is enhanced. At the same time, a resistance law of conductive material: R μL/S, wherein ρ is resistivity of the conductor material, L is conductor length, and S is a conductor cross-sectional area, results in the following. The corresponding areas of the voids are reduced. Therefore, corresponding effective areas of corresponding conductors formed by the first heat dissipating terminals 102 are increased. Grounding impedance of the TCON chip 10 is lowered. The electrical performance of the TCON chip 10 is enhanced.

A corresponding distance between each adjacent set of the first heat dissipating terminals 102, and a corresponding distance between each two opposite sides of the first heat dissipating terminals 102 are determined by the requirements of power amount and electrical performance of the TCON chip 10. As illustrated in FIGS. 2 to 5, usually, a corresponding distance Lout between each adjacent two of the first heat dissipating terminals 102 is 0.8 to 1 mm. When Lout is too small, an adjacent set of the first heat dissipating terminal 102 is prone to be connected together, causing a problem of factors such as gas and stress to affect each other. Therefore, a purpose of improvement is lost. When Lout is too large, a contact area of the first heat dissipating terminals 102 and the GND is too small, thereby affecting heat dissipation performance and electrical performance of the TCON chip 10. A corresponding distance Lin between each two same first heat dissipating terminal-pertaining opposite sides of the first heat dissipating terminals 102 is 1.8 to 2.0 mm. When Lin is too small, it is prone to cause problems such as a defective solder product, insufficient solder joint strength, and false soldering. When Lin is too large, it is prone to cause problems such as empty solder, and a solder ball and an increased stress impact factor. The corresponding distance Lout between each adjacent two of the first heat dissipating terminals 102 and the corresponding distance Lin between each two same first heat dissipating terminal-pertaining opposite sides of the first heat dissipating terminals 102 are arranged so that a contact area of the TCON chip 10 and the GND is large, and at the same time, a corresponding stress impact of each land and a corresponding surface tension impact of the corresponding solder are small. As a result, the two has a good balance. Therefore, an object that heat dissipation performance and electrical performance of the TCON chip 10 are improved is finally achieved.

In some embodiments, as illustrated in FIG. 2(a), in the middle region 1, the first heat dissipating terminals 102 are arranged in a 3*3 array. A corresponding shape and a corresponding size of each of the first heat dissipating terminals 102 are same. The corresponding shape of each of the first heat dissipating terminals 102 is a regular octagon. A corresponding distance Lin between each two same regular octagonal first heat dissipating terminal-pertaining opposite sides of the first heat dissipating terminals 102 is 1.8 mm. A corresponding distance Lout between each adjacent two regular octagonal first heat dissipating terminals of the first heat dissipating terminals 102 is 0.8 mm.

The present embodiments satisfy that the size of the middle region is maximally used, the total occupied area of the first heat dissipating terminals is increased, a solder paste coverage percentage is increased, the contact area of the first heat dissipating terminals and the GND is increased, and the heat dissipation performance and grounding performance of the TCON chip are enhanced, while difficulty in wave soldering and risk of bridging are avoided. At the same time, a minimal value is used as a corresponding size of each two opposite sides of the first heat dissipating terminals. Therefore, gas and stress are facilitated to be released. Mechanical stability of the first heat dissipating terminals is improved. The heat dissipation performance and the electrical performance of the TCON chip are enhanced. In the embodiments, the first heat dissipating terminals may also have one of other polygonal shapes such as a rectangular shape, a circular shape, and an elliptical shape. By using an arrangement that the first heat dissipating terminals having the same size are arranged in an array, the first heat dissipating terminals have a uniform structure, facilitating simple operations.

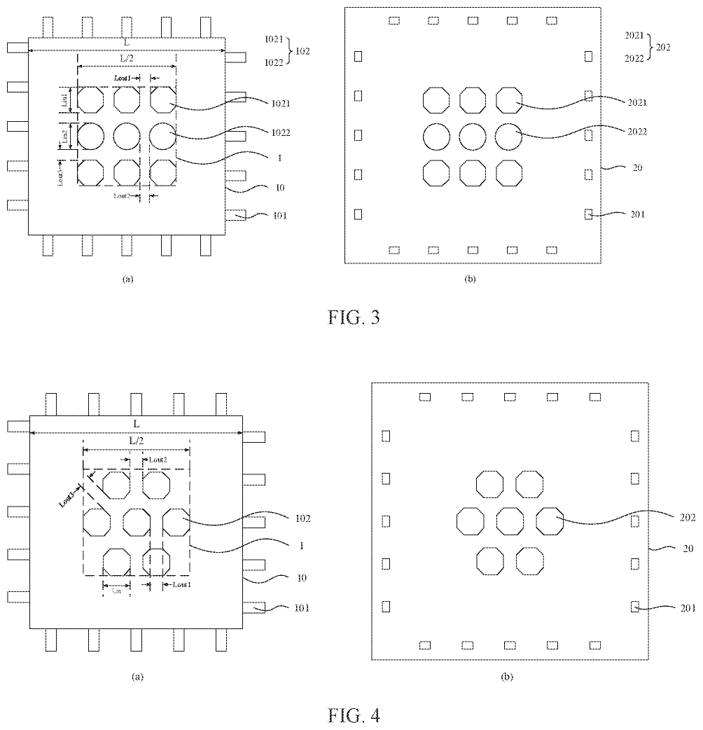

In some embodiments, as illustrated in FIG. 3(a), in the middle region 1, the first heat dissipating terminals 102 are arranged in a 3*3 array. The first heat dissipating terminals 102 include a plurality of regular octagonal first heat dissipating terminals 1021 and a plurality of circular first heat dissipating terminals 1022. The regular octagonal first heat dissipating terminals 1 and the circular first heat dissipating terminals 2 are arranged in a staggered manner. A corresponding distance Lin1 between each two opposite sides of the regular octagonal first heat dissipating terminals 1021 is 1.8 mm. A corresponding diameter Lin2 of each of the circular first heat dissipating terminals 1022 is 1.8 mm. A corresponding distance Lout1 between each adjacent two of the regular octagonal first heat dissipating terminals 1021 is 0.8 mm. A corresponding distance Lout2 between each adjacent two of the circular first heat dissipating terminals 1022 is 0.8 mm. A corresponding distance Lout3 between each adjacent regular octagonal first heat dissipating terminal 1021 and circular first heat dissipating terminal 1022 is also 0.8 mm.

The present embodiments satisfy that in a manner that the regular octagonal first heat dissipating terminals and the circular first heat dissipating terminals are arranged in an array, the size of the middle region is maximally used, the total occupied area of the first heat dissipating terminals is increased, a solder paste coverage percentage is increased, the contact area of the first heat dissipating terminals and the GND is increased, and the heat dissipation performance and grounding performance of the TCON chip are enhanced, while difficulty in wave soldering and risk of bridging are avoided. At the same time, a minimal value is used as a corresponding size of each two opposite sides of the first heat dissipating terminals. Therefore, gas and stress are facilitated to be released. Mechanical stability of the first heat dissipating terminals is improved. The heat dissipation performance and the electrical performance of the TCON chip are enhanced. In the embodiments, the first heat dissipating terminals may also have two or more of other polygonal shapes such as a rectangular shape, a circular shape, and an elliptical shape. The first heat dissipating terminals may be arranged so that each set of alternate rows of the first heat dissipating terminals has a corresponding same shape and size. The first heat dissipating terminals may be arranged so that each set of alternate columns of the first heat dissipating terminals has a corresponding same shape and a plurality of corresponding different sizes, wherein the different sizes correspond to the alternate columns. The first heat dissipating terminals may be arranged so that each set of alternate columns of the first heat dissipating terminals has a plurality of corresponding different shapes and a plurality of corresponding different sizes, wherein the different shapes correspond to the alternate columns, and the different sizes correspond to the alternate columns. The first heat dissipating terminals may also be arranged so that the first heat dissipating terminals have different shapes and different sizes are arranged in a disorderly manner.

In some embodiments, as illustrated in FIG. 4(a), in the middle region 1, the first heat dissipating terminals 102 are arranged in an axisymmetric manner. A corresponding shape and a corresponding size of each of the first heat dissipating terminals 102 are same. The corresponding shape of each of the first heat dissipating terminals 102 is a regular octagon. A corresponding distance Lin between each two same regular octagonal first heat dissipating terminal-pertaining opposite sides of the first heat dissipating terminals 102 is 1.8 mm. Distances Lout1, Lout2, and Lout3 between corresponding sets of adjacent two regular octagonal first heat dissipating terminals of the first heat dissipating terminals 102 are correspondingly 0.8 mm, 1.0 mm, and 0.8 mm.

The present embodiments satisfy that in a manner that seven first heat dissipating terminals having a same size are arranged in the axisymmetric manner, the size of the middle region is maximally used, the total occupied area of the first heat dissipating terminals is increased, a solder paste coverage percentage is increased, the contact area of the first heat dissipating terminals and the GND is increased, and the heat dissipation performance and grounding performance of the TCON chip are enhanced, while difficulty in wave soldering and risk of bridging are avoided. At the same time, large space between the first heat dissipating terminals facilitates gas and stress to be released. Mechanical stability of the first heat dissipating terminals is improved. The heat dissipation performance and the electrical performance of the TCON chip are enhanced. In the embodiments, the first heat dissipating terminals may also have one of other polygonal shapes such as a rectangular shape, a circular shape, and an elliptical shape. By using an arrangement that the first heat dissipating terminals having the same size are arranged in an array, the first heat dissipating terminals have a uniform structure, facilitating simple operations.

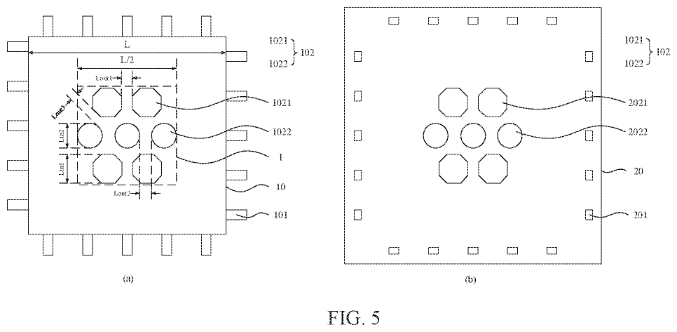

In some embodiments, as illustrated in FIG. 5(a), in the middle region 1, the first heat dissipating terminals 102 are arranged in an axisymmetric manner. The first heat dissipating terminals 102 include a plurality of regular octagonal first heat dissipating terminals 1021 and a plurality of circular first heat dissipating terminals 1022. A corresponding distance Lin1 between each two opposite sides of the regular octagonal first heat dissipating terminals 1021 is 2.0 mm. A corresponding diameter Lin2 of each of the circular first heat dissipating terminals 1022 is 1.8 mm. A corresponding distance Lout1 between each adjacent two of the regular octagonal first heat dissipating terminals 1021 is 1.0 mm. A corresponding distance Lout2 between each adjacent two of the circular first heat dissipating terminals 1022 is 0.8 mm. A corresponding distance Lout3 between each adjacent regular octagonal first heat dissipating terminal 1021 and circular first heat dissipating terminal 1022 is also 0.8 mm.

The present embodiments satisfy that in a manner that the regular octagonal first heat dissipating terminals and the circular first heat dissipating terminals are arranged in an axisymmetric manner, the size of the middle region is greatly used, the total occupied area of the first heat dissipating terminals is increased, a solder paste coverage percentage is increased, the contact area of the first heat dissipating terminals and the GND is increased, and the heat dissipation performance and grounding performance of the TCON chip are enhanced, while difficulty in wave soldering and risk of bridging are avoided. At the same time, large space between the first heat dissipating terminals facilitates gas and stress to be released. Mechanical stability of the first heat dissipating terminals is improved. The heat dissipation performance and the electrical performance of the TCON chip are enhanced. In the embodiments, the first heat dissipating terminals may also have two or more of other polygonal shapes such as a rectangular shape, a circular shape, and an elliptical shape.

In some embodiments, the first heat dissipating terminals may also be arranged in accordance with other rules, or may be arranged in a random manner. The present disclosure is not limited to the four types of arrangement manners in the above embodiments.

In some embodiments, each of the first heat dissipating terminals may be single-layer metal or may also be multi-layer metal. Material of the metal may be any one of, or an alloy of any plurality of titanium (Ti), tungsten (W), aluminum (Al), copper (Cu), nickel (Ni), platinum (Pt), silver (Ag), and gold (Au).

In some embodiments, each second connecting member 40 is corresponding connecting material having a heat conducting function, typically corresponding heat dissipating silicone grease. A principle of the TCON chip that uses the corresponding heat dissipating silicone grease as each second connecting member 40 is similar to that of the TCON chip in the foregoing embodiments that uses the corresponding solder as each second connecting member 40. The corresponding distance between each adjacent two of the first heat dissipating terminals and the corresponding distance between each two same first heat dissipating terminal-pertaining opposite sides of the first heat dissipating terminals cause the contact area of the TCON chip and the GND to be greater, and at the same time, mechanical performance and a bonding effect of each heat dissipating silicone grease are good. As a result, the two has a good balance. Therefore, an object that heat dissipation performance and electrical performance of the TCON chip 10 are improved is finally achieved. Similarly, bridging of one or more of the first heat dissipating terminals and the first signal terminal also need to be avoided. Please refer to the foregoing embodiments for details which are not repeated here.

At the same time, the present disclosure provides a display device, including: any one of the foregoing embodiments of the TCON board, wherein the TCON board includes:

a TCON chip including a first signal terminal and at least two first heat dissipating terminals;

a CB including a second signal terminal disposed corresponding to the first signal terminal, and at least two second heat dissipating terminals disposed corresponding to the corresponding first heat dissipating terminals;

a first connecting member configured to connect the first signal terminal to the second signal terminal; and

at least two second connecting members configured to connect the first heat dissipating terminals to the corresponding second heat dissipating terminals.

The present disclosure provides the display device. The display device includes the TCON board. For the TCON board, the heat dissipating terminals are provided to commonly connect the TCON chip to the CB, increasing a total contact area of the TCON board and the CB. Therefore, heat dissipation efficiency of the TCON chip is improved. At the same time, the heat dissipating terminals greatly reduce a pseudo connection percentage. Even if a truly effective connection point is not formed for one of the heat dissipating terminals, at least one connection point for at least one other corresponding heat dissipating terminal of the heat dissipating terminals is not affected. Hence, heat dissipation performance and electrical performance of the entire TCON chip are avoided to be impacted. The problem that the existing TCON board has the poor heat dissipation performance is alleviated.

In some embodiments, the first heat dissipating terminals are located at a middle region of the TCON chip.

In some embodiments, the middle region has side length half of side length of the TCON chip.

In some embodiments, a corresponding distance between each adjacent two of the first heat dissipating terminals is 0.8 to 1 mm.

In some embodiments, a corresponding distance between each two opposite sides of the first heat dissipating terminals is 1.8 to 2.0 mm.

In some embodiments, all of the first heat dissipating terminals have a same size.

In some embodiments, there are at least two of the first heat dissipating terminals having different corresponding sizes.

In some embodiments, the first heat dissipating terminals are arranged in an array.

In some embodiments, the first heat dissipating terminals are arranged in an axisymmetric manner.

In some embodiments, the first heat dissipating terminals have one or more of an octagonal shape, a quadrilateral shape, and a circular shape.

A principle of the display device provided by some embodiments of the present disclosure is similar to that of the TCON board in the foregoing embodiments. Please refer to the foregoing embodiments for details which are not repeated here.

In accordance with the foregoing embodiments, the following can be known.

The present disclosure provides the TCON board including the TCON chip and the CB. The TCON chip is provided with the first heat dissipating terminals. The CB is provided with the second heat dissipating terminals disposed corresponding to the corresponding first heat dissipating terminals. The first heat dissipating terminals are connected to the corresponding second heat dissipating terminals. The heat dissipating terminals are provided to commonly connect the TCON chip to the CB, increasing a total contact area of the TCON board and the CB. Therefore, heat dissipation efficiency of the TCON chip is improved. At the same time, the heat dissipating terminals greatly reduce a pseudo connection percentage. Even if a truly effective connection point is not formed for one of the heat dissipating terminals, at least one connection point for at least one other corresponding heat dissipating terminal of the heat dissipating terminals is not affected. Hence, heat dissipation performance and electrical performance of the entire TCON chip are avoided to be impacted. The problem that the existing TCON board has the poor heat dissipation performance is alleviated.

In summary, although the present disclosure has been described with preferred embodiments thereof above, it is not intended to be limited by the foregoing preferred embodiments. Persons skilled in the art can carry out many changes and modifications to the described embodiments without departing from the scope and the spirit of the present disclosure. Therefore, the protection scope of the present disclosure is in accordance with the scope defined by the claims.

1. A timing control (TCON) board, comprising:
a TCON chip comprising a first signal terminal and at least two first heat dissipating terminals;
a control board (CB) comprising a second signal terminal disposed corresponding to the first signal terminal, and at least two second heat dissipating terminals disposed corresponding to the corresponding first heat dissipating terminals;
a first connecting member configured to connect the first signal terminal to the second signal terminal; and
at least two second connecting members configured to connect the first heat dissipating terminals to the corresponding second heat dissipating terminals;
wherein all the first heat dissipating terminals are located at a middle region of the TCON chip, and the middle region has a side length that is half of a side length of the TCON chip.

2-3. (canceled)

4. The TCON board of claim 1, wherein a corresponding distance between each adjacent two of the first heat dissipating terminals is 0.8 to 1 mm.

5. The TCON board of claim 1, wherein a corresponding distance between each two opposite sides of the first heat dissipating terminals is 1.8 to 2.0 mm.

6. The TCON board of claim 1, wherein all of the first heat dissipating terminals have a same size.

7. The TCON board of claim 1, wherein there are at least two of the first heat dissipating terminals having different corresponding sizes.

8. The TCON board of claim 1, wherein the first heat dissipating terminals are arranged in an array.

9. The TCON board of claim 1, wherein the first heat dissipating terminals are arranged in an axisymmetric manner.

10. The TCON board of claim 1, wherein the first heat dissipating terminals have one or more of an octagonal shape, a quadrilateral shape, and a circular shape.

11. A display device, comprising: a timing control (TCON) board, wherein the TCON board comprises:
a TCON chip comprising a first signal terminal and at least two first heat dissipating terminals;
a control board (CB) comprising a second signal terminal disposed corresponding to the first signal terminal, and at least two second heat dissipating terminals disposed corresponding to the corresponding first heat dissipating terminals;
a first connecting member configured to connect the first signal terminal to the second signal terminal; and
at least two second connecting members configured to connect the first heat dissipating terminals to the corresponding second heat dissipating terminals;
wherein all the first heat dissipating terminals are located at a middle region of the TCON chip, and the middle region has a side length that is half of a side length of the TCON chip.

12-13. (canceled)

14. The display device of claim 11, wherein a corresponding distance between each adjacent two of the first heat dissipating terminals is 0.8 to 1 mm.

15. The display device of claim 11, wherein a corresponding distance between each two opposite sides of the first heat dissipating terminals is 1.8 to 2.0 mm.

16. The display device of claim 11, wherein all of the first heat dissipating terminals have a same size.

17. The display device of claim 11, wherein there are at least two of the first heat dissipating terminals having different corresponding sizes.

18. The display device of claim 11, wherein the first heat dissipating terminals are arranged in an array.

19. The display device of claim 11, wherein the first heat dissipating terminals are arranged in an axisymmetric manner.

20. The display device of claim 11, wherein the first heat dissipating terminals have one or more of an octagonal shape, a quadrilateral shape, and a circular shape.
